(19) United States
(12) Patent Application Publication
(10) Pub. No.: US 2025/0309568 A1
(43) Pub. Date: Oct. 2, 2025

(54) TERMINAL BLOCK ASSEMBLY

(71) Applicant: SUMITOMO WIRING SYSTEMS, LTD., Mie (JP)

(72) Inventor: Kaishi IZUMI, Mie (JP)

(21) Appl. No.: 18/863,647

(22) PCT Filed: Apr. 26, 2023
(86) PCT No.: PCT/JP2023/016549

§ 371 Date: Nov. 7, 2024

(30) Foreign Application Priority Data
May 9, 2022 (JP) 2022-076913

(51) Int. Cl. H01R 9/24; H01R 13/6581; H01R 13/6593

(52) U.S. Cl. CPC H01R 9/2408; H01R 13/6581; H01R 13/6593

(57) ABSTRACT

A terminal block assembly includes a terminal block that holds terminals of a plurality of electric wires, a shield member, and a metallic plate-shaped bracket that holds the shield member, and the bracket is attached to a protrusion of the device housing. The bracket has a shape that is elongated in a first direction in order to attach the shield member along the first direction. The terminal block has a pin for integrating with the bracket. The bracket includes a coupling plate part having a hole that is larger than an outer diameter of the pin and through which the pin is passed, and a fixing plate part that is fixed to the protrusion in a state of being placed on a tip of the protrusion from an attachment direction orthogonal to the first direction.

### TECHNICAL FIELD

The present disclosure relates to a terminal block assembly.

This application claims priority from Japanese Patent Application No. 2022-076913 filed May 9, 2022, which is hereby incorporated by reference herein.

### BACKGROUND

A terminal block assembly is used to electrically connect electrical devices in a vehicle or the like. For example, in order to connect a motor and an inverter as electrical devices, a terminal block assembly is mounted on a case (device housing) of the motor, and electric wires extending from the terminal block assembly are connected to a terminal block on the inverter side. Patent Document 1 discloses such a terminal block assembly.

### PRIOR ART DOCUMENT

### Patent Document

Patent Document 1: International Publication No. 2015/072335

### SUMMARY OF THE INVENTION

A terminal block assembly according to the present disclosure includes a terminal block that is mounted on a device housing and holds a terminal of a plurality of electric wires, a shield member that is arranged so as to face the plurality of electric wires, and a metallic plate-shaped bracket that holds the shield member, wherein the bracket is attached to a protrusion of the device housing so that the shield member is electrically connectable to the device housing via the bracket, the terminal block has a shape that is elongated in a first direction in order to hold a plurality of the terminals aligned in the first direction, the bracket has a shape that is elongated in the first direction in order to attach the shield member along the first direction, the terminal block has a pin for integrating with the bracket, the bracket includes a coupling plate part having a hole that is larger than an outer diameter of the pin and through which the pin is passed, and a fixing plate part that is fixed to the protrusion in a state of being placed on a tip of the protrusion from an attachment direction orthogonal to the first direction, and the fixing plate part has a contact piece that is capable of contact with the tip in a direction orthogonal to the attachment direction.

### BRIEF DESCRIPTION OF THE DRAWINGS

FIG. 1 is a plan view of a terminal block assembly.

FIG. 2 is a front view of the terminal block assembly.

FIG. 3 is an exploded perspective view of the terminal block assembly.

FIG. 4 is an illustrative diagram showing a portion of the terminal block assembly.

FIG. 5 is an illustrative diagram showing another portion of the terminal block assembly.

FIG. 6 is an enlarged bottom view of a fixing plate part.

FIG. 7 is an illustrative diagram showing a schematic configuration of a conventional terminal block assembly.

### DETAILED DESCRIPTION TO EXECUTE THE INVENTION

### Technical Problem

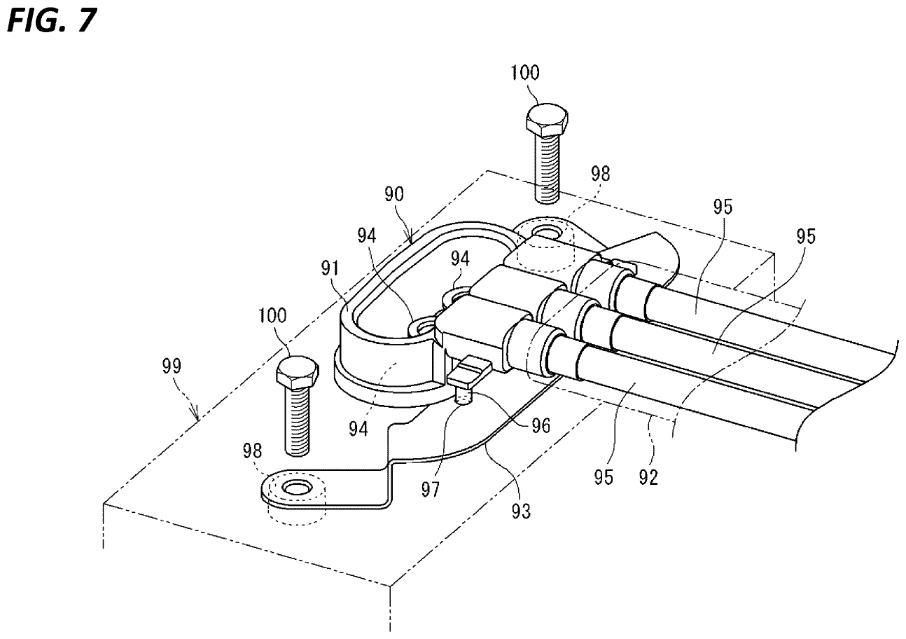

FIG. 7 is an illustrative diagram showing a schematic configuration of a conventional terminal block assembly 90. The terminal block assembly 90 includes a terminal block 91 that holds terminals 94 of a plurality of electric wires 95, a shield member 92 made of braid for the plurality of electric wires 95, and a metal bracket 93 that holds the shield member 92. The terminal block 91 is mounted on a case 99 that is a device housing, and the bracket 93 is fixed to portions 98 of the case 99 by bolts 100, for example. FIG. 7 shows the shield member 92 and the case 99 by two-dot chain lines. The shield member 92 is electrically connectable to the case 99 via the bracket 93, and the configuration including the bracket 93 functions as a ground (earth).

The terminal block 91 has a pin 96 for integrating with the bracket 93, and a hole 97 is provided in a portion of the bracket 93 for letting the pin 96 pass. When the terminal block 91 and the bracket 93 are integrated, in the assembly work, the terminal block assembly 90 can be easily mounted on the case 99 with high work efficiency.

However, during the assembly work, the displacement of the terminal block 91 may be constrained earlier than the bracket 93 on the case 99. Then, the bracket 93 is attached to the portions 98 of the case 99 at both sides by the bolts 100. During the attachment, while the displacement of the terminal block 91 is constrained, if the bracket 93 is displaced by the tightening torque of one bolt 100 used first, for example, a large shear force (excessive force) acts on the pin 96. This may cause breakage of the pin 96.

In view of this, an object of the present disclosure is to provide a terminal block assembly in which a terminal block and a bracket can be integrated and in which no excessive force acts between the terminal block and the bracket.

### Advantageous Effects of Invention

According to the terminal block assembly of the present disclosure, the terminal block and the bracket can be integrated, and no excessive force acts between the terminal block and the bracket.

### Description of Embodiments of the Present Disclosure

Hereinafter, overviews of the embodiments of the present disclosure will be listed and described.

(1) A terminal block assembly of the present embodiment includes a terminal block that is mounted on a device housing and holds a terminal of a plurality of electric wires, a shield member that is arranged so as to face the plurality of electric wires, and a metallic plate-shaped bracket that holds the shield member, wherein the bracket is attached to a protrusion of the device housing so that the shield member is electrically connectable to the device housing via the bracket, the terminal block has a shape that is elongated in a first direction in order to hold a plurality of the terminals aligned in the first direction, the bracket has a shape that is elongated in the first direction in order to attach the shield member along the first direction, the terminal block has a pin for integrating with the bracket, the bracket includes a coupling plate part having a hole that is larger than an outer diameter of the pin and through which the pin is passed, and a fixing plate part that is fixed to the protrusion in a state of being placed on a tip of the protrusion from an attachment direction orthogonal to the first direction, and the fixing plate part has a contact piece that is capable of contact with the tip in a direction orthogonal to the attachment direction.

According to the terminal block assembly of the present embodiment, the pin of the terminal block is inserted into the hole of the coupling plate part of the bracket, so that the terminal block and the bracket are integrated. The hole is larger than the outer diameter of the pin, and the terminal block and the bracket are integrated in a state in which they can be displaced relative to each other. When the terminal block and the bracket are integrated, the terminal block assembly becomes easy to handle, so that the terminal block assembly can be easily mounted on the device housing.

The bracket is attached to the protrusion of the device housing at the fixing plate part. During the attachment, even if the bracket is about to be displaced with a component in the first direction, for example, the contact piece of the bracket comes into contact with the tip of the protrusion, disabling the bracket to be displaced. Even when the displacement of the terminal block is constrained on the device housing, the bracket cannot be displaced relative to the protrusion of the device housing, so that no large shear force (excessive force) acts on the pin of the terminal block, preventing the breakage of the terminal block.

(2) The bracket preferably has the fixing plate part having the contact piece on both sides in the first direction.

With this configuration, the bracket is disabled to be displaced to both sides in the first direction. There may also be cases where the bracket is also disabled to be swung and displaced around the fixing plate part. Therefore, when the fixing plate part is fixed to the protrusion by a bolt, for example, the tightening torque of the bolt disables the bracket to be swung or displaced.

(3) Preferably, the shield member has a sheet shape that is provided so as to face only one side of the plurality of electric wires, and the bracket has an attachment plate part that is provided along an edge part of the sheet-shaped shield member.

In this case, the bracket does not need to have a shape that completely surrounds the sheet-shaped shield member, which enables simplification of the configuration.

(4) In the terminal block assembly according to any one of the above (1) to (3), preferably, the tip of the protrusion has a cylindrical shape, and the contact piece has an arc part with an arc shape along an outer peripheral surface of the tip, and a pair of straight parts that are extended linearly from both ends of the arc part.

In this case, the contact piece of the bracket fits to the tip of the protrusion, which disables displacement of the bracket. The straight parts increase the rigidity of the bracket.

(5) In the terminal block assembly according to the above (4), preferably, the arc part has an arc shape that is continuous along the outer peripheral surface of the tip, and the straight parts and the arc part are continuous with each other. In this case, the rigidity of the bracket is further enhanced.

(6) In the terminal block assembly according to any one of the above (1) to (5), preferably, the terminal block has an arm that is extended in the first direction, and the pin is provided at a leading end of the arm.

In this case, the arm is cantilevered, and the pin is provided at the leading end of the arm. Even with this structure, when the terminal block assembly is mounted on the device housing, no excessive force is applied to the pin and arm of the terminal block, so that the terminal block is prevented from breaking.

(7) In the terminal block assembly according to any one of the above (1) to (6), preferably, a direction of a center line of the pin is the same as the attachment direction.

In this case, the terminal block and the bracket can be displaced in a direction orthogonal to the attachment direction within the range of the gap between the pin and the hole. However, when the fixing plate part of the bracket is placed on the tip of the protrusion of the device housing, the bracket cannot be displaced.

(8) In the terminal block assembly according to any one of the above (1) to (7), preferably, with the terminal block being defined as a second terminal block, the terminal block assembly further includes a first terminal block that is directly attached to the device housing, the second terminal block is fixed to the first terminal block, and the fixing plate part of the bracket is extended to a position of protruding from the first terminal block in the first direction.

In this case, the bracket is fixed to the protrusion of the device housing across the first terminal block. This makes it easier to fix the bracket to the device housing.

### Description of Embodiments of the Present Disclosure

The embodiments of the present disclosure will be described below in detail with reference to the drawings. Note that at least some of the embodiments described below may be combined as desired.

### Overall Configuration of Terminal Block Assembly

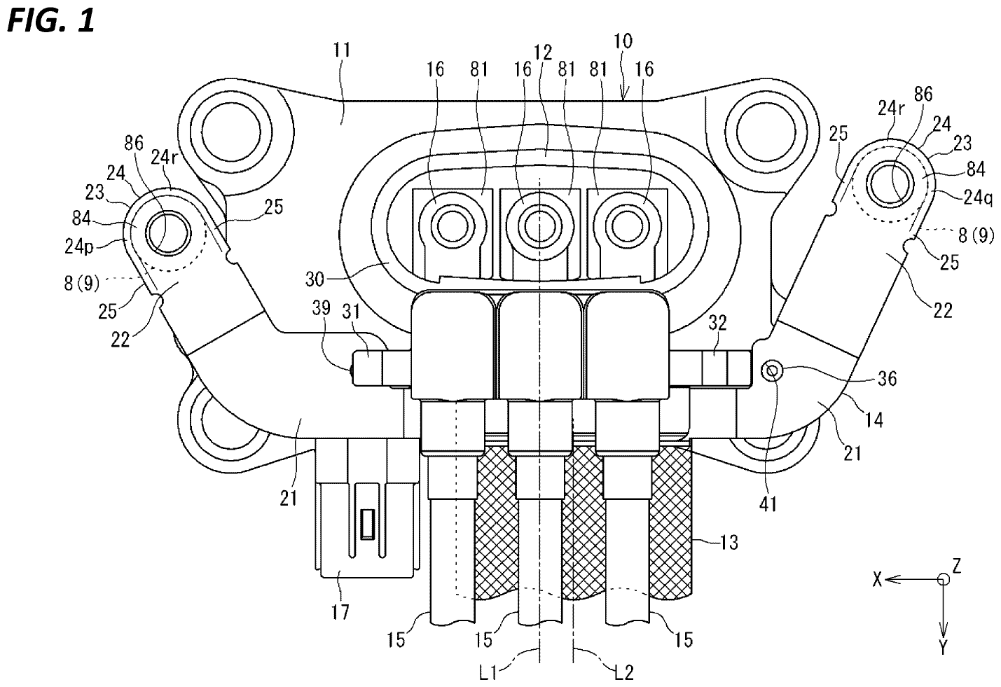

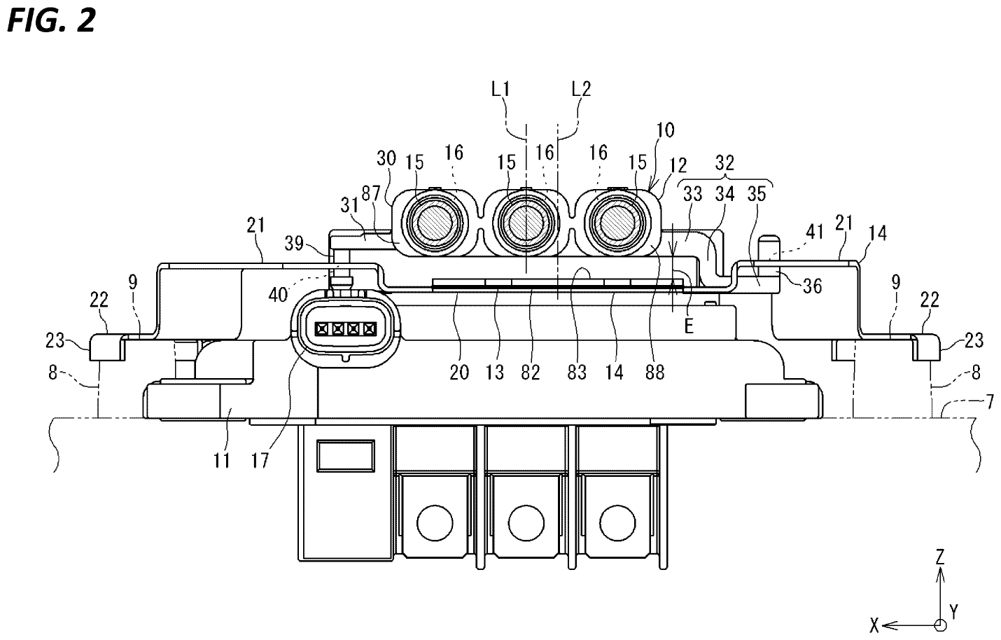

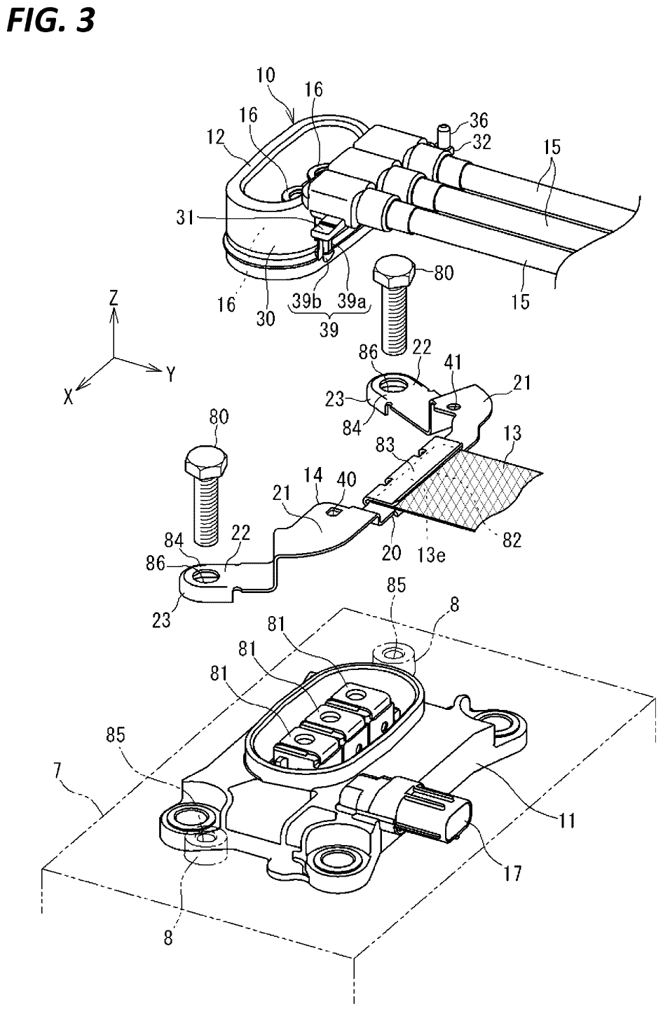

FIG. 1 is a plan view of a terminal block assembly 10. FIG. 2 is a front view of the terminal block assembly 10. FIG. 3 is an exploded perspective view of the terminal block assembly 10. The terminal block assembly 10 is used to connect a plurality of electric devices to each other with electric wires 15. The plurality of electric devices include an in-vehicle motor and inverter. The terminal block assembly 10 of the present embodiment is mounted on a case of the motor. The case will be referred to as a device housing 7 in the following description. In the present embodiment, three-phase (three) electric wires 15 are connected to the terminal block assembly 10, but the number of electric wires 15 can be changed.

The terminal block assembly 10 includes a first terminal block 11, a second terminal block 12, a shield member 13, and a bracket 14. The first terminal block 11 is directly attached to the device housing 7. The first terminal block 11 is fixed to the device housing 7 at its four corners by bolts (not shown). FIGS. 2 and 3 shown the device housing 7 by two-dot chain lines. The second terminal block 12 is attached to the first terminal block 11. The second terminal block 12 is mounted on the device housing 7 with the first terminal block 11 in between. The device housing 7 has two protrusions 8. The bracket 14 is fixed to the protrusions 8 by bolts 80. At least portions of the device housing 7 including the protrusions 8 are made of metal.

The shield member 13 is arranged so as to face the three electric wires 15. The shield member 13 is made of metal and is constituted of braided element wires. The shield member 13 has a rectangular sheet shape and is arranged only on one side of the three electric wires 15. The bracket 14 is made of metal and is a plate-shaped member. The bracket 14 holds the shield member 13. The structure for holding the shield member 13 will be described later.

### First Terminal Block 11 and Second Terminal Block 12

The first terminal block 11 and the second terminal block 12 are made of resin and are formed by injection molding of a thermoplastic resin. The first terminal block 11 has a connector connection part 17. A mating connector of an electric wire extending from another device (not shown) is connected to the connector connection part 17. The connector connection part 17 is provided closer to one side in the width direction of the first terminal block 11 (the left side in FIGS. 1 and 2). When the first terminal block 11 and the second terminal block 12 are combined, the three electric wires 15 and the terminals 16 are located in the center of the first terminal block 11 in the width direction. The first terminal block 11 includes terminal blocks 81 that are electrically connected to the terminals 16 of the three electric wires 15 included in the second terminal block 12.

The second terminal block 12 holds the three terminals 16 of the three electric wires 15. The second terminal block 12 has a housing part 30 that holds the three terminals 16. The terminals 16 are insert-molded into the housing part 30 made of resin, so that the terminals 16 and the housing part 30 are integrated. The housing 30 is fitted to the first terminal block 11, and the second terminal block 12 is fixed to the first terminal block 11. The three terminals 16 are aligned in one direction (first direction). The three electric wires 15 extending from the three terminals 16 are aligned in one direction (first direction). The second terminal block 12 (housing part 30) has a shape that is elongated in the first direction in order to hold the three terminals 16 aligned in the first direction.

The directions related to the terminal block assembly 10 of the present disclosure will be defined here. The direction in which the three (plurality of) terminals 16 are aligned (the first direction) will be defined as width direction. The up-down direction will be defined on the assumption that the first terminal block 11 is the upper terminal block and the second terminal block 12 is the lower terminal block. The up-down direction is a direction that is defined to describe the terminal block assembly 10, and does not need to coincide with the vertically up-down direction when the terminal block assembly 10 is actually mounted on the device housing 7. The direction orthogonal to both the width direction and the up-down direction will be defined as front-rear direction. The electric wires 15 are extended in the front-rear direction. Each drawing shows the XYZ orthogonal coordinates. The X direction is the width direction, the Y direction is the front-rear direction, and the Z direction is the up-down direction.

The second terminal block 12 has pins 36 and 39 for integrating the second terminal block 12 and the bracket 14. More specifically, the second terminal block 12 has a pair of arms 31 and 32. The arms 31 and 32 are extended from the housing part 30 to both sides in the width direction. The first pin 39 is provided at the leading end of the first arm 31. The second pin 36 is provided at the leading end of the second arm 32. The first arm 31, the second arm 32, the first pin 39, and the second pin 36 are integrally molded with the housing part 30 and are made of resin.

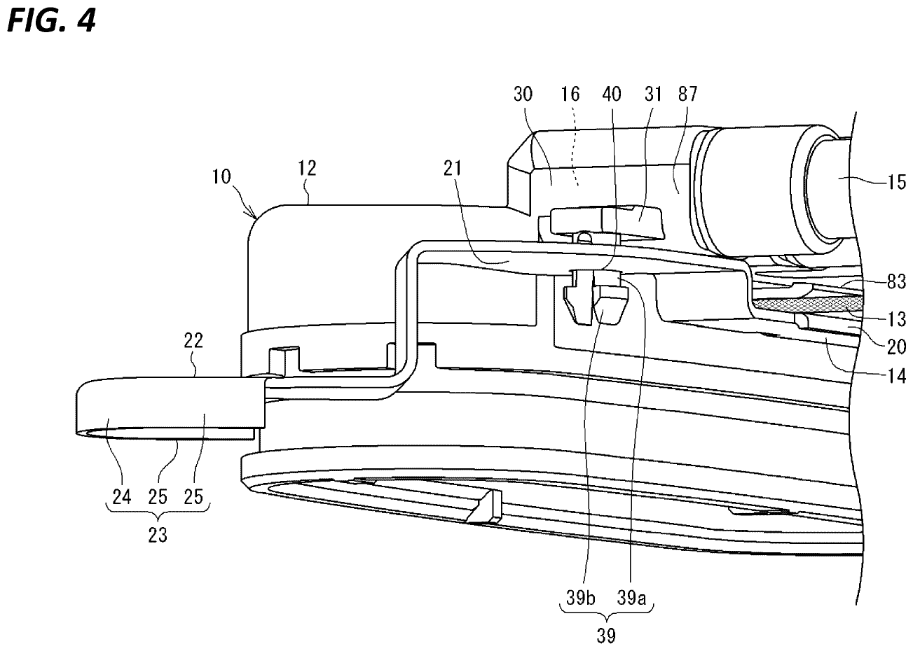

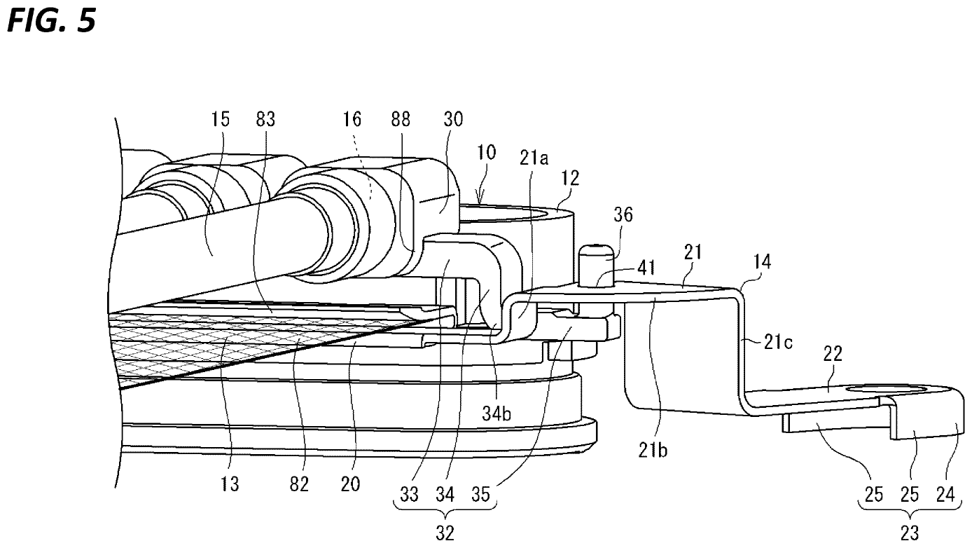

FIG. 4 is an illustrative diagram showing a part of the terminal block assembly 10 (one side in the width direction). FIG. 5 is an illustrative diagram showing another part of the terminal block assembly 10 (the other side in the width direction). As shown in FIG. 4, the bracket 14 has a first hole 40 through which the first pin 39 is passed. The first hole 40 is larger than the outer diameter (cross section) of the first pin 39 (pin body part 39a). The first pin 39 has the pin body part 39a with a uniform outer diameter shape along its center line (half circle) and a locking part 39b larger in outer diameter than the pin body part 39a. The locking part 39b is larger than the first hole 40 and is elastically deformable. In the present embodiment, the pin body part 39a and the locking part 39b are shaped in halves, so that the first pin 39 is elastically deformable as a whole. When the first pin 39 is passed through the first hole 40, the locking part 39b contracts from the expanded shape, and after the first pin 39 is passed through the first hole 40, the locking part 39b returns to the expanded shape due to its resilience. The locking part 39b prevents the first pin 39 from coming out of the bracket 14.

As shown in FIG. 5, the bracket 14 has a second hole 41 through which the second pin 36 is passed. The inner diameter of the second hole 41 is larger than the outer diameter of the second pin 36. The cross section of the second pin 36 along its center line has the same shape (circular shape) as the second hole 41.

With the first pin 39 and the second pin 36, the bracket 14 and the second terminal block 12 are relatively displaceable in the up-down direction, but are inseparable from each other (integrated). Within the range where the pins 39, 36 and the holes 40, 41 contact each other, the bracket 14 and the second terminal block 12 are slightly displaceable in the width direction and the front-rear direction.

### Shielding Member 13 and Bracket 14

As shown in FIG. 3, the bracket 14 has a shape elongated in the width direction (X direction) in order to attach an edge part 13e of the shield member 13 along the width direction. The bracket 14 is made of metal (for example, stainless steel). The bracket 14 has an attachment plate part 20, coupling plate parts 21, and fixing plate parts 22. The attachment plate part 20 is a part for attaching the edge part 13e of the shield member 13. The attachment plate part 20 is provided along the edge part 13e of the shield member 13 and is elongated in the width direction. The attachment plate part 20 has a base piece 82 located below the edge part 13e of the shield member 13, and a bent piece 83 for sandwiching the edge part 13e from above between the bent piece 83 and the base piece 82. The bracket 14 has a bent part in the coupling plate part 21, but the bent part has a plate shape, not a shape that surrounds the entire circumference of the sheet-shaped shield member 13.

The shield member 13 is provided on the bracket 14 below the three electric wires 15 and closer to the other side in the width direction (the right side in FIGS. 1 and 2) with respect to the electric wires 15. In FIGS. 1 and 2, a center line passing through the center of the bundle of three electric wires 15 in the widthwise direction is shown as “L1”, and a center line passing through the center of the shield member 13 in the widthwise direction is shown as “L2”. The center lines L1 and L2 do not coincide with each other in the widthwise direction.

As shown in FIG. 3, the coupling plate parts 21 are provided on both sides of the attachment plate part 20 in the width direction. The coupling plate part 21 on one side in the width direction has the first hole 40 through which the first pin 39 is passed. The coupling plate part 21 on the other side in the width direction has the second hole 41 through which the second pin 36 is passed.

The bracket 14 has the fixing plate parts 22 on both side in the width direction. The fixing plate parts 22 are extended from the coupling plate parts 21. The fixing plate parts 22 on both sides are fixed by the bolts 80 to the two protrusions 8 that are portions of the device housing 7. As shown in FIG. 1, the bracket 14 is elongated in the width direction (X direction) and is bent at the coupling plate parts 21 to one side in the front-rear direction (Y direction). The fixing plate parts 22 on both sides in the width direction are extended so as to widen a spacing between the fixing plate parts 22 in the width direction. The fixing plate parts 22 on both sides in the width direction are extended to positions protruding from the first terminal block 11 in the width direction. Therefore, the bracket 14 is fixed to the protrusions 8 of the device housing 7 so as to cross over the first terminal block 11 in the width direction.

The fixing plate parts 22 are fixed to the protrusions 8 in a state of being placed on tips 9 of the protrusions 8 (see FIG. 2). The direction from top to bottom (up-down direction) is the attachment direction of the bracket 14 to the protrusions 8. The fixing plate parts 22 are fixed to the protrusions 8 in a state of being placed on the tips 9 of the protrusions 8 in the attachment direction orthogonal to the width direction (X direction). When the bracket 14 is attached to the protrusions 8, the shield member 13 can be electrically connected to the device housing 7 via the bracket 14. The shield member 13 is electrically connected to the reference potential point through the device housing 7.

The protrusions 8 has screw holes 85 (see FIG. 3) that are opened on the upper surface. The bolts 80 are fastened into the screw holes 85, whereby the bracket 14 is fixed to the device housing 7. The flat plate parts 84 of the fixing plate parts 22 have holes 86 through which the screw shafts of the bolts 80 are passed.

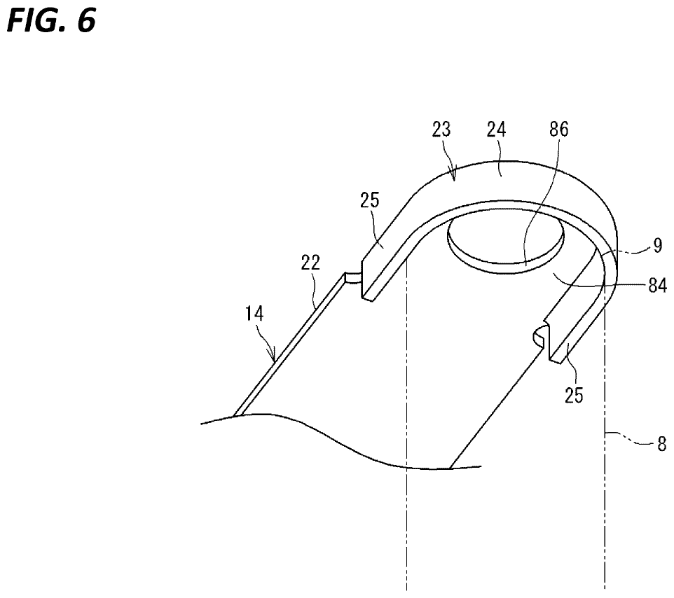

FIG. 6 is an enlarged bottom view of the fixing plate part 22. In FIG. 6, the protrusion 8 is shown by two-dot chain lines. As described above, the attachment direction of the bracket 14 to the protrusions 8 is a direction from top to bottom (up-down direction). Each fixing plate part 22 has a contact piece 23 that can contact the tip 9 of the protrusion 8 at the time of attachment in a direction orthogonal to the attachment direction. The contact pieces 23 are provided on a pair of fixing plate parts 22 on both sides of the bracket 14 in the width direction (see FIG. 3). In the present embodiment, the contact pieces 23 can contact the tips 9 of the protrusions 8 in the front-rear direction and the width direction.

Referring to FIG. 6, the tip 9 of each protrusion 8 has a cylindrical shape. Each contact piece 23 has an arc part 24 and a pair of straight parts 25 in order to contact the tip 9 in the front-rear direction and the width direction. The arc part 24 and the straight parts 25 have a shape that is bent at a right angle from the flat plate part 84 of the fixing plate part 22 that is placed on the upper surface of the protrusion 8. The arc part 24 has an arc shape along the outer peripheral surface of the tip 9. The straight parts 25 are extended linearly from both ends of the arc part 24. The arc part 24 is provided within a range of 180 degrees with reference to the center of the tip 9. The arc part 24 has an arc shape that is continuous along the outer peripheral surface of the tip 9. The straight parts 25 and the arc part 24 are continuous.

The functions of the contact pieces 23 of the bracket 14 will be described (see FIGS. 1 to 3).

The direction of the center lines of the first pin 39 and the second pin 36 is the same as the attachment direction (up-down direction) of the bracket 14 to the protrusions 8. Before the fixing plate parts 22 on both sides of the bracket 14 in the width direction are placed on the protrusions 8, the bracket 14 can be displaced in the directions (width direction and front-rear direction) orthogonal to the attachment direction relative to the second terminal block 12. The range in which the bracket 14 can be displaced is the range of the gap between the first pin 39 and the first hole 40 and the range of the gap between the second pin 36 and the second hole 41.

When the fixing plate parts 22 of the bracket 14 are placed on the protrusions 8, in the fixing plate part 22 on one side in the width direction of the bracket 14 (the left side in FIG. 1), the tip 9 is interposed in the width direction between a portion 24p of the arc part 24 and the straight part 25 on one side opposite to the portion 24p, out of the contact piece 23. In the fixing plate part 22 of the bracket 14 on the other side in the width direction (the right side in FIG. 1), the tip 9 is interposed in the width direction between the portion 24p of the arc part 24 and the straight part 25 on one side opposite to the portion 24p, out of the contact piece 23. This restricts the displacement of the bracket 14 in the width direction.

In each of the fixing plate parts 22 on both sides of the bracket 14 in the width direction, the tip 9 is interposed in the front-rear direction between the other portion 24r of the arc part 24 and the straight part 25 on one side opposite to the other portion 24r, out of the contact piece 23. This restricts the displacement of the bracket 14 in the front-rear direction.

As described above, when the bracket 14 is placed on the tips 9 of the protrusions 8, the displacement of the bracket 14 in the width direction and the front-rear direction is restricted by the contact pieces 23. As a result, no shear force (excessive force) acts on the pins 39 and 36.

### Coupling Structure Between Second Terminal Block 12 and Bracket 14

Before the terminal block assembly 10 is mounted on the device housing 7, the second terminal block 12 and the bracket 14 are assembled and integrated in advance. The structure for integration will be described.

As shown in FIGS. 2 and 4, the first arm 31 is extended from a first resin part 87 that partially covers one terminal 16 of the housing part 30 to one side in the width direction. The first resin part 87 to which the first arm 31 is connected is a resin part that covers the connection part between the terminal 16 on one side in the width direction and the electric wire 15. The first pin 39 protrudes downward from the leading end of the first arm 31.

As shown in FIGS. 2 and 5, the second arm 32 is extended from a second resin part 88 that partially covers another terminal 16 of the housing part 30 to the other side in the width direction. The second arm 32 has a base part 33 that continues from the housing part 30, an end part 35 on the side opposite to the housing part 30, and a middle part 34 that connects the base part 33 and the end part 35. The base part 33 is extended from the second resin part 88 that partially covers the other terminal 16 to the other side in the width direction. The second resin part 88 to which the second arm 32 is connected is a resin part that covers the connection part between the terminal 16 on the other side in the axial direction and the electric wire 15. The middle part 34 is extended downward from the base part 33. The end part 35 is extended from a lower portion 34b of the middle part 34 to the other side in the width direction. The end part 35 has the second pin 36 that protrudes upward.

With the second pin 36 passed through the second hole 41, the first pin 39 is passed through the first hole 40. As described above, the locking part 39b is contracted when the first pin 39 is being passed through the first hole 40. After the first pin 39 is passed through, the locking part 39b expands due to its resilience. Accordingly, the first pin 39 is retained in the bracket 14. In an assembly of the second terminal block 12 and the bracket 14, when the bracket 14 is about to fall off downward from the second terminal block 12, the coupling plate part 21 of the bracket 14 comes into contact with the second arm 32, thereby preventing the bracket 14 from falling off. In the assembly, when the second terminal block 12 is about to fall off downward from the bracket 14, the first arm 31 comes into contact with the coupling plate part 21 of the bracket 14, thereby preventing the second terminal block 12 from falling off.

### Terminal Block Assembly 10 of Present Embodiment

The terminal block assembly 10 of the present embodiment illustrated in FIGS. 1 to 3 includes the second terminal block 12 that holds the terminals 16 of the three electric wires 15, the shield member 13 that is provided so as to face the three electric wires 15, and the metallic plate-shaped bracket 14 that holds the shield member 13. The bracket 14 is attached to the protrusions 8 of the device housing 7. Accordingly, the shield member 13 is electrically connected to the device housing 7 via the bracket 14.

The second terminal block 12 has a shape elongated in the width direction in order to hold the three terminals 16 aligned in the width direction (X direction). The bracket 14 has a shape elongated in the width direction in order to attach the shield member 13 along the width direction. The second terminal block 12 has the first pin 39 and the second pin 36 for integrating with the bracket 14. The bracket 14 has the coupling plate parts 21 and the fixing plate parts 22. The coupling plate part 21 on one side in the width direction has the first hole 40 through which the first pin 39 is passed. The coupling plate part 21 on the other side in the width direction has the second hole 41 through which the second pin 36 is passed.

The pins 39 and 36 of the second terminal block 12 are inserted into the holes 40 and 41 of the bracket 14, so that the second terminal block 12 and the bracket 14 are integrated. This makes it easier to handle the terminal block assembly 10, and facilitates the work of mounting the terminal block assembly 10 on the device housing 7. The bracket 14 is attached to the protrusions 8 of the device housing 7 at its fixing plate parts 22. In the attachment direction of the bracket 14 from top to bottom, the bracket 14 is placed on the tips 9 of the protrusions 8, and then the fixing plate parts 22 are fixed to the protrusions 8. The fixing plate parts 22 have the contact pieces 23 that can come into contact with the tips 9 in the direction orthogonal to the attachment direction.

At the time of attachment of the bracket 14 to the device housing 7, when the bracket 14 is placed on the tips 9 of the protrusions 8, even if the bracket 14 is about to be displaced with a component in the width direction, for example, the displacement of the bracket 14 is disabled because the contact pieces 23 come into contact with the tips 9 of the protrusions 8. Therefore, no large shear force (excessive force) acts on the pins 36 and 39 of the second terminal block 12, and breakage of the second terminal block 12 can be prevented.

In the present embodiment, the second terminal block 12 is attached to the first terminal block 11, and the first terminal block 11 is fixed to the device housing 7. After that, the bracket 14 is fixed to the protrusions 8. The second terminal block 12 is constrained from displacing on the device housing 7 earlier than the bracket 14. Even if the second terminal block 12 is constrained earlier from displacing on the device housing 7, the contact pieces 23 disables the displacement of the bracket 14 relative to the protrusions 8 of the device housing 7.

For example, when the fixing plate parts 22 are fixed to the protrusions 8 by the bolts 80, the bracket 14 may be about to swing around the protrusions 8 due to the tightening torque of the bolts 80. According to the present embodiment, as described above, the contact pieces 23 disable the displacement of the bracket 14 relative to the protrusions 8. Therefore, no large shear force (excessive force) acts on the pins 36 and 39.

The second terminal block 12 has the first arm 31 and the second arm 32 that are extended to both sides in the width direction. The first pin 39 is provided at the leading end of the first arm 31. The second pin 36 is provided at the leading end of the second arm 32. The first arm 31 and the second arm 32 are cantilevered, and the pins 39 and 36 are provided at the leading ends of the arms 31 and 32. Even with this structure, when the terminal block assembly 10 is mounted on the device housing 7, no excessive force is applied to the pins 39, 36 and the arms 31, 32 as described above, so that the second terminal block 12 is prevented from breaking.

The bracket 14 has the fixing plate parts 22 with the contact pieces 23 on both sides in the width direction. Therefore, even if the bracket 14 is mounted with the bolts 80 first on one side or first on the other side in the width direction, the bracket 14 will not be swung or displaced by the tightening torque of the bolts 80. Furthermore, after the bracket 14 is attached to the protrusions 8, even if the bracket 14 is about to be displaced in the front-rear direction or the width direction, the displacement is restricted by the contact pieces 23, and no shear force acts on the pins 36 and 39.

As shown in FIG. 6, the tips 9 of the protrusions 8 have a cylindrical shape. Each contact piece 23 has the arc part 24 that have an arc shape along the outer peripheral surface of the tip 9, and the pair of straight parts 25. The straight parts 25 are extended linearly from both ends of the arc part 24. This makes it possible to effectively restrict the displacement of the bracket 14 in the front-rear direction and the width direction. Furthermore, even if the flat plate parts 84 of the fixing plate parts 22 are thin, the straight parts 25 enhance rigidity.

Each contact piece 23 is molded by plastic deformation. For ease of molding, a slit may be provided between the arc part 24 and the straight parts 25, or a slit may be provided in the middle of the arc part 24. However, in the present embodiment, each contact piece 23 is formed without a slit. That is, each arc part 24 has a continuous arc shape along the outer peripheral surface of the tip 9. The straight parts 25 and the arc part 24 are continuous. This configuration further enhances the rigidity of the fixing plate part 22.

### Others

In the above embodiment, the protrusions 8 of the device housing 7 have a cylindrical shape, and the contact pieces 23 of the bracket 14 have the arc parts 24 to match the cylindrical shape. The shape of the contact pieces 23 can be changed according to the shape of the protrusions 8. Although each contact piece 23 has the arc part 24 and the two opposing straight parts 25 in the embodiment, one or both of the straight parts 25 may be omitted. The contact pieces 23 are merely shaped so as to be able to contact the tips 9 of the protrusions 8 in the direction orthogonal to the attachment direction (direction from top to bottom).

The above-described embodiment is illustrative in all respects and is not restrictive. The scope of the present invention is indicated by the scope of claims, not by the above-described embodiment, and is intended to include all modifications within a meaning and scope equivalent to the scope of claims.

### LIST OF REFERENCE NUMERALS

7 Device housing
8 Protrusion
9 Tip
10 Terminal block assembly
11 First terminal block
12 Second terminal block
13 Shield member
13e Edge part
14 Bracket
15 Electric wire
16 Terminal
17 Connector connection part
20 Attachment plate part
21 Coupling plate part
22 Fixing plate part
23 Contact piece
24 Arc part
24p Portion
24q Portion
24r Other portion
25 Straight part
30 Housing part
31 First arm
32 Second arm
33 Base part
34 Middle part
34b Lower part
35 Tip
36 Second pin
39 First pin
39a Pin body part
39b Locking part
40 First hole
41 Second hole
81 Terminal block
82 Base piece
83 Bent piece
84 Flat plate part
85 Screw hole
86 Hole
87 First resin part
88 Second resin part
90 Terminal block assembly
91 Terminal block
92 Shield member
93 Bracket
94 Terminal
95 Electric wire
96 Pin
97 Hole
98 Portion
99 Case
L1 Center line
L2 Center line

1. A terminal block assembly comprising:
a terminal block that is mounted on a device housing and holds a terminal of a plurality of electric wires;
a shield member that is arranged so as to face the plurality of electric wires; and
a metallic plate-shaped bracket that holds the shield member,
wherein the bracket is attached to a protrusion of the device housing so that the shield member is electrically connectable to the device housing via the bracket,
the terminal block has a shape that is elongated in a first direction in order to hold a plurality of the terminals aligned in the first direction,
the bracket has a shape that is elongated in the first direction in order to attach the shield member along the first direction,
the terminal block has a pin for integrating with the bracket,
the bracket includes a coupling plate part having a hole that is larger than an outer diameter of the pin and through which the pin is passed, and a fixing plate part that is fixed to the protrusion in a state of being placed on a tip of the protrusion from an attachment direction orthogonal to the first direction, and
the fixing plate part has a contact piece that is capable of contact with the tip in a direction orthogonal to the attachment direction.

2. The terminal block assembly according to claim 1, wherein the bracket has the fixing plate part having the contact piece on both sides in the first direction.

3. The terminal block assembly according to claim 1,
wherein the shield member has a sheet shape that is provided so as to face only one side of the plurality of electric wires, and
the bracket has an attachment plate part that is provided along an edge part of the sheet-shaped shield member.

4. The terminal block assembly according to claim 1,
wherein the tip of the protrusion has a cylindrical shape, and
the contact piece has an arc part with an arc shape along an outer peripheral surface of the tip, and a pair of straight parts that are extended linearly from both ends of the arc part.

5. The terminal block assembly according to claim 4,
wherein the arc part has an arc shape that is continuous along the outer peripheral surface of the tip, and
the straight parts and the arc part are continuous with each other.

6. The terminal block assembly according to claim 1,
wherein the terminal block has an arm that is extended in the first direction, and
the pin is provided at a leading end of the arm.

7. The terminal block assembly according to claim 1, wherein a direction of a center line of the pin is the same as the attachment direction.

8. The terminal block assembly according to claim 1,
with the terminal block being defined as a second terminal block, the terminal block assembly further includes a first terminal block that is directly attached to the device housing,
the second terminal block is fixed to the first terminal block, and
the fixing plate part of the bracket is extended to a position of protruding from the first terminal block in the first direction.
